(19) United States
(12) Patent Application Publication
(10) Pub. No.: US 2018/0164628 A1
(43) Pub. Date: Jun. 14, 2018

(54) PROCESSING SYSTEM OF FLEXIBLE DISPLAY DEVICE AND METHOD THEREOF

(71) Applicant: WUHAN CHINA STAR OPTOELECTRONICS TECHNOLOGY CO., LTD., Wuhan, Hubei (CN)

(72) Inventor: Haiyang SHEN, Wuhan, Hubei (CN)

(21) Appl. No.: 15/327,388

(22) PCT Filed: Dec. 23, 2016
(86) PCT No.: PCT/CN2016/111633

§ 371 Date: Jan. 19, 2017

(30) Foreign Application Priority Data
Dec. 12, 2016 (CN) 201611142225.6

(51) Int. Cl. G02F 1/1333; H01L 27/32; H01L 51/00; H01L 51/52; G02F 1/13; G09G 3/00

(52) U.S. Cl. CPC G02F 1/133305; H01L 27/3276; G09G 3/006; H01L 51/52; G02F 1/1309; H01L 51/0097

(57) ABSTRACT

A processing system of a flexible display device and a method thereof are described. The processing system includes a processing machine configured to process the flexible display device; a first collecting device configured to collect an outstanding flexible display device in form of a curling status for providing the outstanding flexible display device to the processing machine at a planar manner; and a second collecting device configured to receive a processed flexible display device from the processing machine in a planar manner for collecting the processed flexible display device at the curling status. The present invention can increase the processing efficiency of the flexible display device.

### BACKGROUND OF THE INVENTION

### Field of Invention

The present invention relates to a processing technical field of a flexible display device, and more particularly to a processing system of a flexible display device and a method thereof.

### Description of Prior Art

A conventional processing system of a display device includes a cassette and a processing machine, where the cassette is configured to store and transfer a sheet-shaped display device (e.g., a flexible display device), and the processing machine is used to process the sheet-shaped display devices provided by the cassette.

In an operation of processing system, there are some problems as follows.

(1) The cassette for storing and transferring sheet-shaped display devices occupies a large space.

(2) It is required to spend a lot of time when the sheet-shaped display devices are transferred to the processing machine. In other words, the processing efficiency of the conventional processing system for the display devices is too low.

Consequently, there is a need to develop a novel technical solution to solve the above-mentioned problems.

### SUMMARY OF THE INVENTION

Therefore, one objective of the present invention is to provide a processing system of a flexible display device and a method thereof to increase the processing efficiency of the flexible display device.

Based on the above objective, the present invention sets forth the following technical solutions. A processing system of a flexible display device includes at least one processing machine configured to process the flexible display device; at least one first collecting device configured to collect an outstanding flexible display device in form of a curling status, and to provide the outstanding flexible display device, which is in the curling status, to the processing machine at a planar manner; at least one second collecting device configured to receive a processed flexible display device from the processing machine in a planar manner, and to collect the processed flexible display device, which is in the planar manner, at the curling status; wherein the first collecting device is further configured to unfold at least one portion of the outstanding flexible display device, which is at a curling status, to form a planar shape, and the first collecting device is further configured to provide the planar shape of the outstanding flexible display device to the processing machine; wherein before the first collecting device is configured to provide the outstanding flexible display device to the processing machine, the outstanding flexible display device has been transferred to the processing machine; wherein after the second collecting device is configured to receive the processed flexible display device from the processing machine, the processed flexible display device has been removed away from the processing machine.

In the processing system of the flexible display device, the outstanding flexible display device collected by the first collecting device and the processed flexible display device collected by the second collecting device are disposed on a flexible carrying device.

In the processing system of the flexible display device, the flexible carrying device is either glass having a predetermined thickness or a protective film.

In the processing system of the flexible display device, the first collecting device and the second collecting device are cylinders.

In another embodiment, a processing system of a flexible display device includes at least one processing machine configured to process the flexible display device; at least one first collecting device configured to collect an outstanding flexible display device in form of a curling status, and to provide the outstanding flexible display device, which is in the curling status, to the processing machine at a planar manner; and at least one second collecting device configured to receive a processed flexible display device from the processing machine in a planar manner, and to collect the processed flexible display device, which is in the planar manner, at the curling status.

In the processing system of the flexible display device, the first collecting device is further configured to unfold at least one portion of the outstanding flexible display device, which is at a curling status, to form a planar shape, and the first collecting device is further configured to provide the planar shape of the outstanding flexible display device to the processing machine.

In the processing system of the flexible display device, the outstanding flexible display device collected by the first collecting device and the processed flexible display device collected by the second collecting device are disposed on a flexible carrying device.

In the processing system of the flexible display device, the flexible carrying device is either glass having a predetermined thickness or a protective film.

In the processing system of the flexible display device, the first collecting device and the second collecting device are cylinders.

In the processing system of the flexible display device, the outstanding flexible display device and the processed flexible display device are collected by the surface of the cylinders.

In the processing system of the flexible display device, before the first collecting device is configured to provide the outstanding flexible display device to the processing machine, the outstanding flexible display device has been transferred to the processing machine; and after the second collecting device is configured to receive the processed flexible display device from the processing machine, the processed flexible display device has been removed away from the processing machine.

In the processing system of the flexible display device, the processing system further includes a transporting device for transporting the first collecting device and/or the second collecting device.

Still in another embodiment, a processing method of a flexible display device includes the steps of: (A) collecting, by a first collecting device, an outstanding flexible display device in form of a curling status; (B) providing, by the first collecting device, the outstanding flexible display device disposed in the curling status to a processing machine at a planar manner; (C) processing, by the processing machine, the flexible display device; and (D) receiving, by a second collecting device, a processed flexible display device in a planar shape from the processing machine 101, and collecting the processed flexible display device in the planar shape using a curling status.

In the processing method of the flexible display device, wherein the step (B) further includes the steps: (b1) unfolding, by the first collecting device, at least one portion of the outstanding flexible display device, which is at a curling status, to form a planar shape; and (b2) providing, by the first collecting device, the planar shape of the outstanding flexible display device to the processing machine.

In the processing method of the flexible display device, the outstanding flexible display device collected by the first collecting device and the processed flexible display device collected by the second collecting device are disposed on a flexible carrying device.

In the processing method of the flexible display device, the flexible carrying device is either glass having a predetermined thickness or a protective film.

In the processing method of the flexible display device, the first collecting device and the second collecting device are cylinders.

In the processing method of the flexible display device, the outstanding flexible display device and the processed flexible display device are collected by the surface of the cylinders.

In the processing method of the flexible display device, after the step (A) and before the step (B), the processing method further includes the step of transporting the first collecting device which collects the outstanding flexible display device to a position of the processing machine before the first collecting device provides the outstanding flexible display device to the processing machine; wherein after the step (D), the processing method further includes the step of transporting the second collecting device which collects the processed flexible display device away from the processing machine after the second collecting device receives the processed flexible display device from the processing machine.

In the processing method of the flexible display device, the processing method further includes a step (E) transporting, by a transporting device, the first collecting device and/or the second collecting device.

In comparison to the conventional technique, the first collecting device of the present invention is configured to collect the outstanding flexible display device and provides the outstanding flexible display device the processing machine. Thus, since the processing machine continuously providing the outstanding flexible display device, the processing efficiency of the outstanding flexible display device is increased. Furthermore, the present invention can save the occupied space to store and transfer the flexible display device.

### BRIEF DESCRIPTION OF THE DRAWINGS

FIG. 1 is an illustrative side view of a processing system of a flexible display device according to one embodiment of the present invention;

FIG. 2 is an illustrative top view of the processing system of a flexible display device according to one embodiment of the present invention;

FIG. 3 is a flowchart of a processing method of the processing system of a flexible display device according to one embodiment of the present invention;

FIG. 4 is a flowchart of providing, by a first collecting device in FIG. 3, an outstanding flexible display device in form of a curling status to a processing machine at a planar manner according to one embodiment of the present invention; and

FIG. 5 is a flowchart of receiving, by a second collecting device in FIG. 3, a processed flexible display device from the processing machine in a planar manner, and collecting the processed flexible display device in form of the planar manner at the curling status according to one embodiment of the present invention.

### DETAILED DESCRIPTION OF THE PREFERRED EMBODIMENTS

The following embodiments refer to the accompanying drawings for exemplifying specific implementable embodiments of the present invention.

A term “processing” indicates at least one kind of meanings including production, machining and treatment.

A term “flexible display device” indicates a final product, a semi-product of the flexible display device, and some parts of the flexible display device (e.g., a flexible substrate, and/or an array substrate including the flexible substrate and a thin film transistor array).

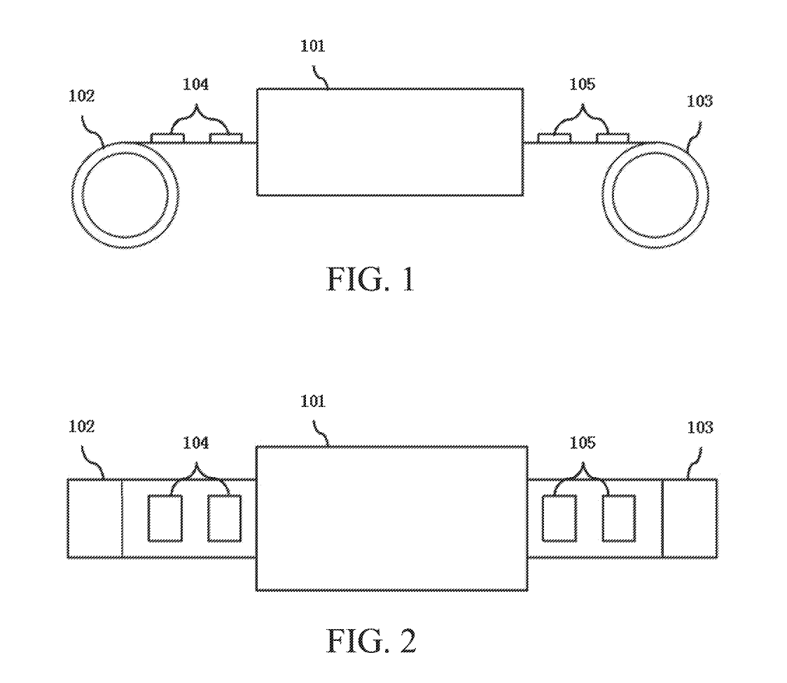

FIG. 1 is an illustrative side view of a processing system of a flexible display device according to one embodiment of the present invention. FIG. 2 is an illustrative top view of the processing system of a flexible display device according to one embodiment of the present invention.

The processing system of a flexible display device of the present invention includes at least one processing machine 101, at least one first collecting device 102, and at least one second collecting device 103.

The at least one processing machine 101 is configured to process the flexible display device. For example, the processing machine 101 performs a heating step, a hardening step, a coating step, a step of UV light, and an etching step on the flexible display device.

The at least one first collecting device 102 is configured to collect an outstanding flexible display device 104 and to provide the outstanding flexible display device 104 to the processing machine 101.

The at least one second collecting device 103 is configured to receive a processed flexible display device 105 from the processing machine 101, and collect the processed flexible display device 105.

In the processing system of the flexible display device of the present invention, the first collecting device 102 is configured to collect an outstanding flexible display device 104, which is at a planar manner, in form of a curling status. The first collecting device 102 is further configured to provide the outstanding flexible display device 104 which is in the curling status, to a processing machine 101 at a planar manner.

The second collecting device 103 receives the processed flexible display device 106 from the processing machine 101 in a planar manner, and the second collecting device 103 is further configured to collect the processed flexible display device 105 in form of the planar manner at the curling status.

In one embodiment, the shapes of the first collecting device 102 and the second collecting device 103 are circular column. For example, the first collecting device 102 and the second collecting device 103 are cylinders. The outstanding flexible display device 104 and the processed flexible display device 105 are collected by the surface of the cylinders.

Before the first collecting device 102 is configured to provide the outstanding flexible display device 104 to the processing machine 101, the outstanding flexible display device 104 has been transferred to the processing machine 101. After the second collecting device 103 is configured to receive the processed flexible display device 105 from the processing machine 101, the processed flexible display device 105 has been removed away from the processing machine 101.

In the processing system of the flexible display device of the present invention, the first collecting device 102 is further configured to unfold at least one portion of the outstanding flexible display device 104, which is at a curling status, to form a planar shape. The first collecting device 102 is further configured to provide the planar shape of the outstanding flexible display device 104 to the processing machine 101.

In the processing system of the flexible display device of the present invention, the outstanding flexible display device 104 collected by the first collecting device 102 and the processed flexible display device 105 collected by the second collecting device 103 are disposed on a flexible carrying device.

In the processing system of the flexible display device of the present invention, the flexible carrying device is either glass (e.g., ultra-thin glass) having a predetermined thickness or a protective film.

In the processing system of the flexible display device of the present invention, before a first collecting device 102 provides an outstanding flexible display device 104 in form of a curling status to a processing machine 101 at a planar manner, the first collecting device 102 is moved to an input end of the processing machine 101 and butts the input end of the processing machine 101.

Before the second collecting device 103 receives the processed flexible display device 105 from the processing machine 101 in a planar manner, the second collecting device 103 is moved to an output end of the processing machine 101 and butts the output end of the processing machine 101.

The processing system of the flexible display device of the present invention further includes a transporting device for transporting the first collecting device 102 and/or the second collecting device 103.

In one embodiment, the transporting device is configured to transport the first collecting device 102 to the input end of the processing machine 101 and/or to move the second collecting device 103 away from the output end of the processing machine 101.

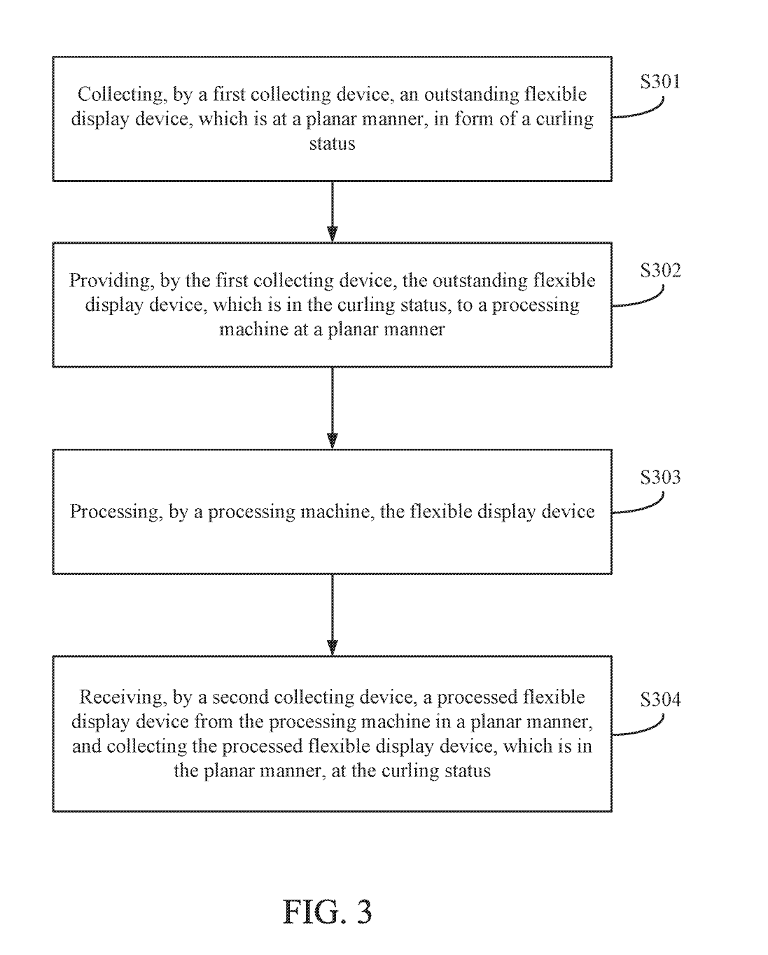

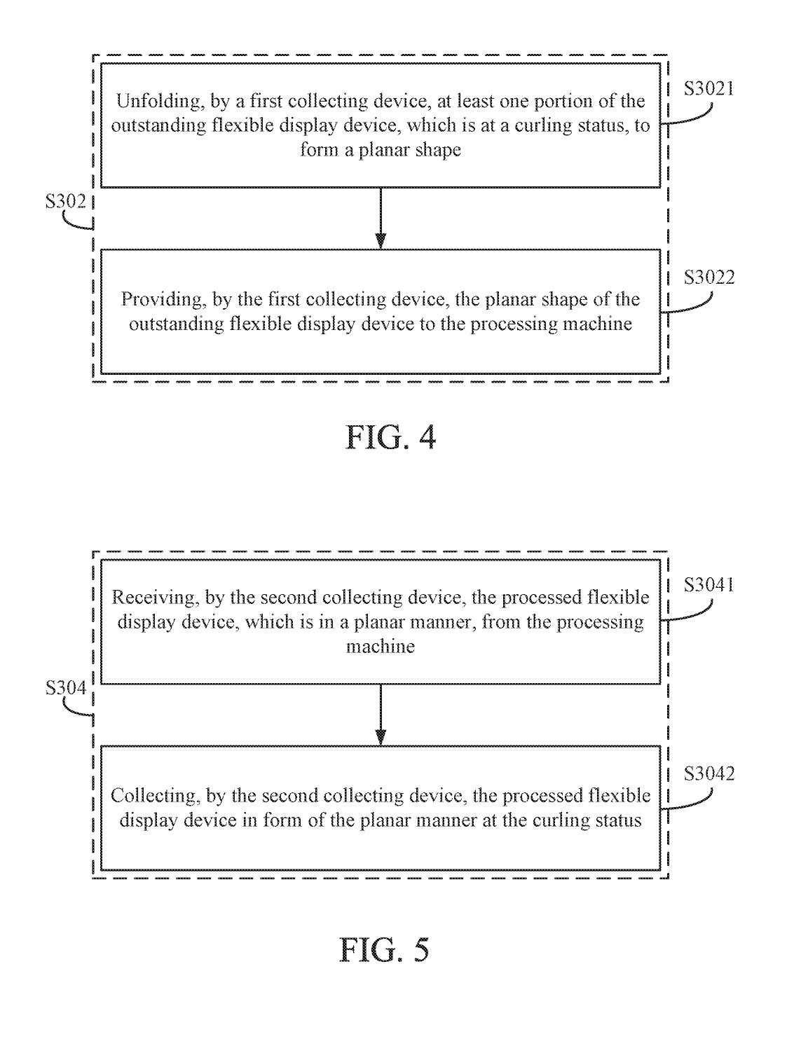

Please refer to FIGS. 3-5. FIG. 3 is a flowchart of a processing method of the processing system of a flexible display device according to one embodiment of the present invention. FIG. 4 is a flowchart of providing, by a first collecting device 102 in FIG. 3, an outstanding flexible display device 104 in form of a curling status to a processing machine 101 at a planar manner according to one embodiment of the present invention. FIG. 5 is a flowchart of receiving, by a second collecting device 103 in FIG. 3, a processed flexible display device 105 from the processing machine in a planar manner, and collecting the processed flexible display device 105 in form of the planar manner 101 at the curling status according to one embodiment of the present invention.

As shown in FIG. 3, the processing method of the processing system of the flexible display device including the following steps.

In the step S301, the first collecting device 102 is configured to collect an outstanding flexible display device 104, which is at a planar manner, in form of a curling status.

In the step S302, the first collecting device 102 is further configured to provide the outstanding flexible display device 104, which is in the curling status, to a processing machine 101 at a planar manner.

In the step S303, the processing machine 101 is configured to process the flexible display device. For example, the processing machine 101 performs a heating step, a hardening step, a coating step, a step of UV light, and an etching step on the flexible display device.

In the step S304, the second collecting device 103 is configured to receive a processed flexible display device 105 from the processing machine 101, and collect the processed flexible display device 105.

In one embodiment of FIG. 4, during the step S302, the first collecting device 102 provides the outstanding flexible display device 104, which is in the curling status, to a processing machine 101 at a planar manner.

In one embodiment of FIG. 5, the step S304 including the following steps.

In the step S3041, the second collecting device 103 receives the processed flexible display device 106, which is in a planar manner, from the processing machine 101.

In the step S3042, the second collecting device 103 is further configured to collect the processed flexible display device 105 in form of the planar manner at the curling status.

In one embodiment, the shapes of the first collecting device 102 and the second collecting device 103 are circular column. For example, the first collecting device 102 and the second collecting device 103 are cylinders. The outstanding flexible display device 104 and the processed flexible display device 105 are collected by the surface of the cylinders.

After the step S301 and before the step S302, the processing method of the processing system of the flexible display device further includes the following step.

Before the first collecting device 102 is configured to provide the outstanding flexible display device 104 to the processing machine 101, the first collecting device 102 which collects the outstanding flexible display device 104 is transported to a position of the processing machine 101.

After the step S304, the processing method of the processing system of the flexible display device farther includes the following steps.

After the second collecting device 103 is configured to receive the processed flexible display device 105 from the processing machine 101, the second collecting device 103 which collects the processed flexible display device 105 is transported away from the processing machine 101.

In the processing system of the flexible display device of the present invention, the step S302 further includes the following steps.

In the step S3021, the first collecting device 102 is further configured to unfold at least one portion of the outstanding flexible display device 104, which is at a curling status, to form a planar shape.

In the step S3022, the first collecting device 102 is further configured to provide the planar shape of the outstanding flexible display device 104 to the processing machine 101.

In the processing system of the flexible display device of the present invention, the outstanding flexible display device 104 collected by the first collecting device 102 and the processed flexible display device 105 collected by the second collecting device 103 are disposed on a flexible carrying device.

In the processing system of the flexible display device of the present invention, the flexible carrying device is either glass (e.g., ultra-thin glass) or a protective film.

In the processing system of the flexible display device of the present invention, before the step S302, the processing method of the processing system of the flexible display device further includes the following step.

Before a first collecting device 102 provides an outstanding flexible display device 104 in form of a curling status to a processing machine 101 at a planar manner, the first collecting device 102 is moved to an input end of the processing machine 101 and butts the input end of the processing machine 101.

Before the step S304, the processing method of the processing system of the flexible display device further includes the following step.

Before the second collecting device 103 receives the processed flexible display device 105 from the processing machine 101 in a planar manner, the second collecting device 103 is moved to an output end of the processing, machine 101 and butts the output end of the processing machine 101.

The processing method of the processing system of the flexible display device further includes the following step.

A transporting device transports the first collecting device 102 and/or the second collecting device 103.

In one embodiment, the transporting device for transporting the first collecting device 102 and/or the second collecting device 103 includes the following step.

The transporting device is configured to transport the first collecting device 102 to the input end of the processing machine 101.

The transporting device is configured to move the second collecting device 103 away from the output end of the processing machine 101.

Based on the above-mentioned technical solution, the first collecting device 102 with a cylindrical shape is configured to collect the outstanding flexible display device 104 and provides the outstanding flexible display device 104 the processing machine 101. Thus, since the processing machine 101 continuously providing the outstanding flexible display device 104, the processing efficiency of the outstanding flexible display device 104 is increased. Furthermore, the present invention can save the occupied space to store and transfer the flexible display device.

As is understood by a person skilled in the art, the foregoing preferred embodiments of the present invention are illustrative rather than limiting of the present invention. It is intended that they cover various modifications and similar arrangements be included within the spirit and scope of the present invention, the scope of which should be accorded the broadest interpretation so as to encompass all such modifications and similar structures.

1. A processing system of a flexible display device, comprising:
at least one processing machine configured to process the flexible display device;
at least one first collecting device configured to collect an outstanding flexible display device in form of a curling status, and to provide the outstanding flexible display device, which is in the curling status, to the processing machine at a planar manner;
at least one second collecting device configured to receive a processed flexible display device from the processing machine in a planar manner, and to collect the processed flexible display device, which is in the planar manner, at the curling status;
wherein the first collecting device is further configured to unfold at least one portion of the outstanding flexible display device, which is at a curling status, to form a planar shape, and the first collecting device is further configured to provide the planar shape of the outstanding flexible display device to the processing machine;
wherein before the first collecting device is configured to provide the outstanding flexible display device to the processing machine, the outstanding flexible display device has been transferred to the processing machine;
wherein after the second collecting device is configured to receive the processed flexible display device from the processing machine, the processed flexible display device has been removed away from the processing machine.

2. The processing system of the flexible display device of claim 1, wherein the outstanding flexible display device collected by the first collecting device and the processed flexible display device collected by the second collecting device are disposed on a flexible carrying device.

3. The processing system of the flexible display device of claim 2, wherein the flexible carrying device is either glass having a predetermined thickness or a protective film.

4. The processing system of the flexible display device of claim 1, wherein the first collecting device and the second collecting device are cylinders.

5. A processing system of a flexible display device, comprising:
at least one processing machine configured to process the flexible display device;
at least one first collecting device configured to collect an outstanding flexible display device in form of a curling status, and to provide the outstanding flexible display device, which is in the curling status, to the processing machine at a planar manner; and
at least one second collecting device configured to receive a processed flexible display device from the processing machine in a planar manner, and to collect the processed flexible display device, which is in the planar manner, at the curling status.

6. The processing system of the flexible display device of claim 5, wherein the first collecting device is further configured to unfold at least one portion of the outstanding flexible display device, which is at a curling status, to form a planar shape, and the first collecting device is further configured to provide the planar shape of the outstanding flexible display device to the processing machine.

7. The processing system of the flexible display device of claim 5, wherein the outstanding flexible display device collected by the first collecting device and the processed flexible display device collected by the second collecting device are disposed on a flexible carrying device.

8. The processing system of the flexible display device of claim 7, wherein the flexible carrying device is either glass having a predetermined thickness or a protective film.

9. The processing system of the flexible display device of claim 5, wherein the first collecting device and the second collecting device are cylinders.

10. The processing system of the flexible display device of claim 9, wherein the outstanding flexible display device and the processed flexible display device are collected by the surface of the cylinders.

11. The processing system of the flexible display device of claim 5, wherein:
before the first collecting device is configured to provide the outstanding flexible display device to the processing machine, the outstanding flexible display device has been transferred to the processing machine; and
after the second collecting device is configured to receive the processed flexible display device from the processing machine, the processed flexible display device has been removed away from the processing machine.

12. The processing system of the flexible display device of claim 5, wherein further comprising a transporting device for transporting the first collecting device and/or the second collecting device.

13. A processing method of a flexible display device, the processing method comprising the steps of:
(A) collecting, by a first collecting device, an outstanding flexible display device in form of a curling status;
(B) providing, by the first collecting device, the outstanding flexible display device disposed in the curling status to a processing machine at a planar manner;
(C) processing, by the processing machine, the flexible display device; and
(D) receiving, by a second collecting device, a processed flexible display device in a planar shape from the processing machine 101, and collecting the processed flexible display device in the planar shape using a curling status.

14. The processing method of the flexible display device of claim 13, wherein the step (B) further comprises the steps:
(b1) unfolding, by the first collecting device, at least one portion of the outstanding flexible display device, which is at a curling status, to form a planar shape; and
(b2) providing, by the first collecting device, the planar shape of the outstanding flexible display device to the processing machine.

15. The processing method of the flexible display device of claim 13, wherein the outstanding flexible display device collected by the first collecting device and the processed flexible display device collected by the second collecting device are disposed on a flexible carrying device.

16. The processing method of the flexible display device of claim 15, wherein the flexible carrying device is either glass having a predetermined thickness or a protective film.

17. The processing method of the flexible display device of claim 13, wherein the first collecting device and the second collecting device are cylinders.

18. The processing method of the flexible display device of claim 17, wherein the outstanding flexible display device and the processed flexible display device are collected by the surface of the cylinders.

19. The processing method of the flexible display device of claim 13, wherein after the step (A) and before the step (B), the processing method further comprises the step:
transporting the first collecting device which collects the outstanding flexible display device to a position of the processing machine before the first collecting device provides the outstanding flexible display device to the processing machine;
wherein after the step (D), the processing method further comprises the step:
transporting the second collecting device which collects the processed flexible display device away from the processing machine after the second collecting device receives the processed flexible display device from the processing machine.

20. The processing method of the flexible display device of claim 13, further comprising a step of:
(E) transporting, by a transporting device, the first collecting device and/or the second collecting device.
